(19) United States
(12) Patent Application Publication
(10) Pub. No.: US 2006/0124346 A1
(43) Pub. Date: Jun. 15, 2006

(54) Current collection board for fuel cell

(76) Inventors: Hsi-Ming Shu, Sin Jhuang (TW); Feng-Yi Deng, Taipei (TW); Tsang-Ming Chang, Taipei (TW); Wei-Li Huang, Taipei (TW)

Correspondence Address: G. LINK Co., LTD, 3550 Bell Road, MINOOKA, IL, 60447, US

(21) Appl. No.: 11/298,460

(22) Filed: Dec. 12, 2005

(30) Foreign Application Priority Data
Dec. 14, 2004 (TW) 093220124

(51) Int. Cl. H05K 1/00

(52) U.S. Cl. 174/250

(57) ABSTRACT

A current collection board for a fuel cell is described. The current collection board includes a plate body having a substrate made of a printed circuit board, and at least one current collection circuitry disposed on the surface of the plate body. Furthermore, the current collection board is fabricated according to the shapes and areas of the membrane electrode assemblies. The fabricating method is thus simple and costs less.

### FIELD OF THE INVENTION

The present invention relates to a current collection board for a fuel cell, and more particularly, to a current collection board using a printed circuit board as its substrate, which is easily fabricated and is inexpensive.

### BACKGROUND OF THE INVENTION

A conventional fuel cell includes the components like an anode current collection board, a cathode current collection board and at least one membrane electrode assembly (MEA), wherein these components are assembled compactly to form the cell. Consequently, the anode current collection board and the cathode current collection board applied to a certain type of fuel cell are not suitable for other types of cells. It is also difficult for traditional structures of the anode current collection board and the cathode current collection board to fit them for manifold MEAs, especially for newly-developed MEAs. As a result, such newly-developed MEAs' quality is not tested and verified except if another special anode current collection boards and cathode current collection boards are manufactured.

Therefore, an improved current collection board that is easily fabricated and inexpensive is needed to overcome the aforesaid disadvantages.

### SUMMARY OF THE INVENTION

It is a primary object of the invention to provide a current collection board for a fuel cell, which is easily fabricated and inexpensive.

It is another object of the invention to provide a simple fabricated and inexpensive current collection board for a fuel cell, which is formed corresponding to the shapes and areas of the membrane electrode assemblies.

In accordance with the objects of the invention, a current collection board for a fuel cell is disclosed. The current collection board comprises a plate body having a substrate made of a printed circuit board, and at least a current collection circuitry disposed on the surface of the plate body.

### BRIEF DESCRIPTION OF THE DRAWINGS

The foregoing aspects, as well as many of the attendant advantages and features of this invention will become more apparent by reference to the following detailed description, when taken in conjunction with the accompanying drawings, wherein:

FIG. 1 illustrates a current collection board for a fuel cell according to one embodiment of the present invention;

FIG. 2 is a side view of FIG. 1;

FIG. 3 shows a plate body having electrical device thereon according to one embodiment of the present invention; and

FIG. 4 shows a plate body having electrical interfaces according to one embodiment of the present invention.

### DETAILED DESCRIPTION OF THE INVENTION

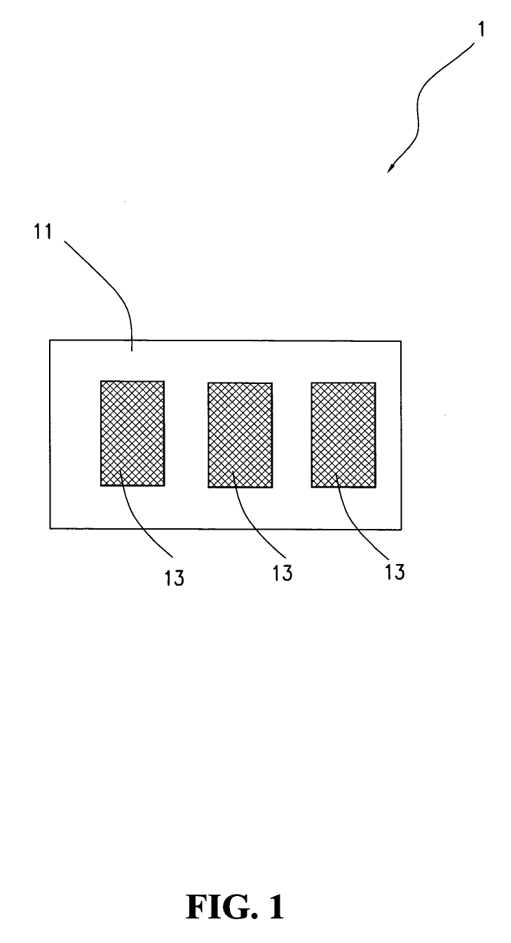

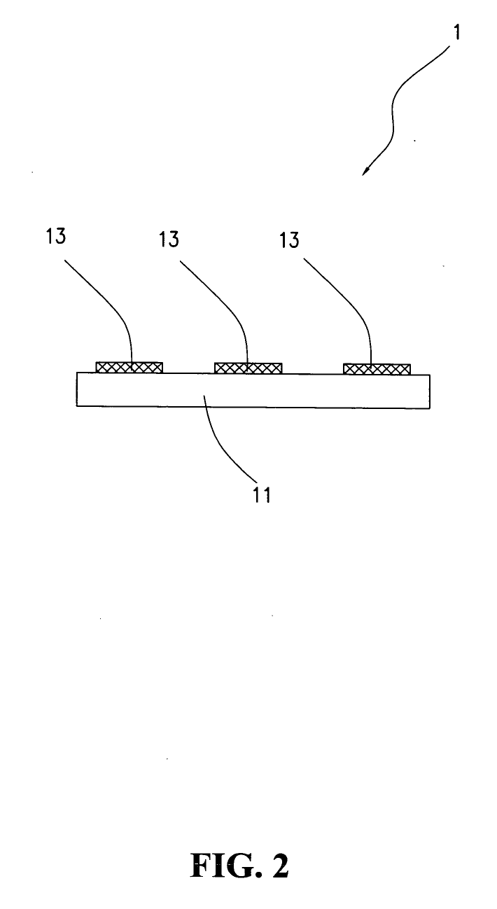

FIG. 1 illustrates a current collection board for a fuel cell according to one embodiment of the invention, and FIG. 2 shows its side view. The current collection board 1 includes a plate body 11 and one or more current collection circuitries 13. The current collection board 1 may be fabricated using a printed circuit board (PCB), such as a copper foil printed circuit board. For example, the current collection circuitries 13 are formed by means of the copper foil printed circuit board and PCB processes. Additionally, the shapes and the areas of the current collection circuitries 13 are designed based on those of membrane electrode assemblies (MEAs) (not shown). For instance, the current collection circuitries 13 are rectangular structures while the MEAs are rectangles. It is noted that the rectangular current collection circuitries 13 are merely an exemplar, which are not limited to the invention.

The current collection circuitry 13 is made of a conductive material, such as copper foil covering the surface of a PCB, a metal lamina, metal foil, a graphite board, and so on. Moreover, there are two ways to manufacture the current collection circuitries 13. One is to utilize metal foil originally covering the surface of the plate body 11 to form the current collection circuits 13. The other way is to form the current collection circuitries 13 and the plate body 11, respectively, and then to compress the current collection circuitries 13 onto the surface of the sealed plate body 11.

In additional to the aforesaid rectangular structure, the current collection circuitry 13 may be a frame structure with a hollow portion in the middle region thereof, a network structure, or a flat structure composed of lines.

Since the current collection board 1 may be an anode current collection board or a cathode current collection board, the surfaces of the current collection circuitries 13 are further treated by, for example, performing a protective process or an acid-proof process, or coating a material with good conductivity, for accommodating themselves to different applications of fuels. Therefore, the current collection circuitries 13 are protected from erosion of fuels, and the ability of collecting current thereof is enhanced.

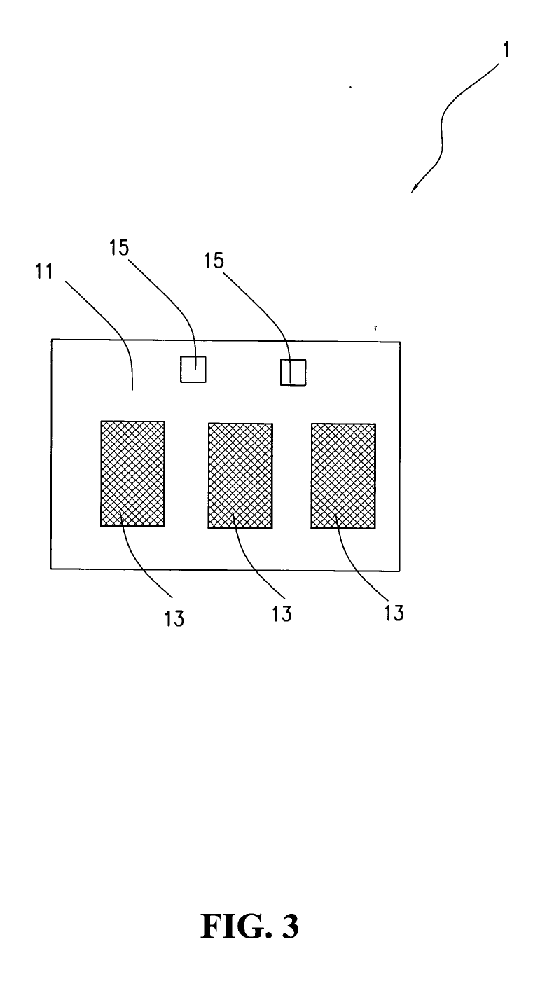

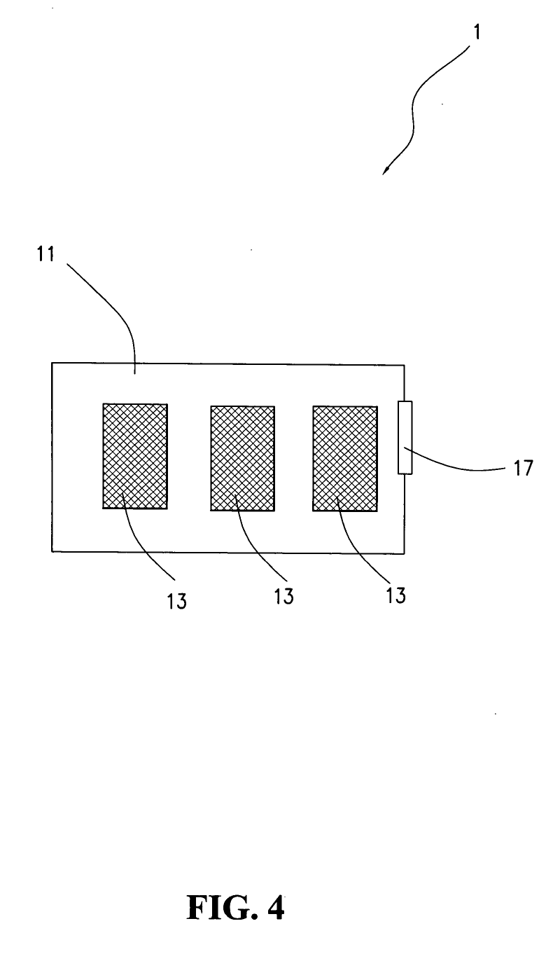

Referring to FIG. 3, the current collection board 1 also comprises one or more electrical devices 15 on the plate body 11. The electrical device 15 is, for example, active electrical component, a passive electrical component, a sensor, an integrated circuit device, a microprocessor, a constant voltage regulator, or a constant current regulator. The current collection board 1 further comprises an electrical interface 17, as shown in FIG. 4. The electrical interface 17 is, for instance, a golden finger, a connector, a cable, or a cable having a connector. Through the electrical interface 17, the current collection board 1 can transmit signals, so as to communicate with external surroundings.

The current collection circuitries 13 can be formed separately on the top and bottom surfaces of the plate body 11. For example, a two-sided copper foil printed circuit board is used to fabricate a current collection board 1 with current collection circuitries 13 at its two sides. The current collection circuitries 13 can be formed, of course, on a single side of the plate body 11. For example, a single-sided copper foil printed circuit board is used to fabricate a current collection board 1 with current collection circuitries 13 at its single side. Furthermore, pluralities of through holes (not shown) are disposed within a region defined by the current collection circuitry 13, in order to make fuels flow into corresponding MEA.

The electrical circuit interface board 1 can be applied to any kinds of fuel cells, such as fuel cells with methanol fuels, or fuel cells with liquid fuels, gaseous fuels or solid fuels.

The current collection board of the invention possesses some advantages and dominant improvements, which are summarized as follows:

1. The current collection board has utility since it can be manufactured by means of PCB accompanying a simple and inexpensive process; and

2. The current collection board is a multi-function current collection board because it also integrates circuit devices and electrical interfaces.

While the invention has been particularly shown and described with reference to the preferred embodiments thereof, these are, of course, merely examples to help clarify the invention and are not intended to limit the invention. It will be understood by those skilled in the art that various changes, modifications, and alterations in form and details may be made therein without departing from the spirit and scope of the invention, as set forth in the following claims.

What is claimed is:

1. A current collection board for a fuel cell, said current collection board comprising:
a plate body having a board made of a printed circuit board; and
at least one current collection circuitry made of a conductive material and disposed on a surface of said plate body.

2. The current collection board of claim 1, wherein said current collection circuit is made of metal foil covering said plate body.

3. The current collection board of claim 1, wherein said current collection circuitry is a pre-fabricated current collection circuitry, and then the pre-fabricated current collection circuitry is compressed in a sealed manner onto the surface of said plate body.

4. The current collection board of claim 1, wherein said current collection circuitry is separately disposed on a top surface and a bottom surface of said plate body.

5. The current collection board of claim 1, wherein said current collection circuitry is a network structure.

6. The current collection board of claim 1, wherein said current collection circuitry is a frame structure with a hollow portion in a middle region.

7. The current collection board of claim 1, wherein said current collection circuitry is a flat structure composed of lines.

8. The current collection board of claim 1, wherein a surface of said current collection circuitry is treated by a protective process and/or an acid-proof process.

9. The current collection board of claim 1, wherein a surface of said current collection circuitry is coated by a metal material with good conductivity.

10. The current collection board of claim 1, further comprising a plurality of through holes disposed within a region defined by said current collection circuitry.

11. The current collection board of claim 1, wherein said plate body is a copper foil printed circuit board.

12. The current collection board of claim 1, further comprising at least one electrical device disposed on said plate body.

13. The current collection board of claim 1, further comprising an electrical interface disposed on said plate body.

14. The current collection board of claim 13, wherein said electrical interface is a golden finger.

15. The current collection board of claim 13, wherein said electrical interface is a connector.

16. The current collection board of claim 13, wherein said electrical interface is a cable.

17. The current collection board of claim 13, wherein said electrical interface comprises a cable having a connector.
